(19) United States
(12) Patent Application Publication
(10) Pub. No.: US 2026/0282657 A1
(43) Pub. Date: Sep. 17, 2026

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Ju MEI, Beijing (CN); Jianpeng WU, Beijing (CN); Xiang LUO, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/995,899

(22) PCT Filed: Aug. 21, 2023
(86) PCT No.: PCT/CN2023/114073

§ 371 Date: Jan. 17, 2025

(30) Foreign Application Priority Data
Sep. 29, 2022 (CN) 202211203597.0

(51) Int. Cl. H10K 59/122

(52) U.S. Cl. CPC H10K 59/122

(57) ABSTRACT

A display panel includes a drive backplane, a pixel definition layer disposed on a side of the drive backplane, and a plurality of light-emitting devices separated by the pixel definition layer. Each of the light-emitting devices includes a first electrode, at least one first common layer, at least one second common layer, and a common electrode layer sequentially stacked in a direction away from the drive backplane; first common layers of the plurality of light-emitting devices are integrated as a whole; and second common layers of the plurality of light-emitting devices are integrated as a whole. An orthogonal projection of the first common layer on the drive backplane is within an orthogonal projection of the second common layer on the drive backplane.

### CROSS-REFERENCE TO RELATED APPLICATION

This disclosure claims priority to Chinese Patent Application No. 202211203597.0, filed on Sep. 29, 2022 and entitled “Display Panel and Display Apparatus”, the entire content of which is incorporated herein by reference in its entirety.

### TECHNICAL FIELD

This disclosure relates to the field of display technology and, more particularly, to a display panel and a display apparatus.

### BACKGROUND

In a manufacturing process of an OLED (organic light-emitting diode) display panel, a film layer in an OLED light-emitting device is typically formed through evaporation using a metal mask. In the related art, the mask is prone to scratching the film layer formed by evaporation, causing an evaporation material to peel off.

It should be noted that information disclosed in the Background is only used to acquire a better understanding of the background of this disclosure and therefore may include information that does not constitute the related art already known to those skilled in the art.

### SUMMARY

An objective of this disclosure is to provide a display panel and a display apparatus, so as to improve quality of the display panel.

To achieve the above objective, this disclosure adopts following technical solutions.

According to a first aspect of this disclosure, there is provided a display panel, including a drive backplane, a pixel definition layer disposed on a side of the drive backplane, and a plurality of light-emitting devices separated by the pixel definition layer, wherein each of the light-emitting devices includes a first electrode, at least one first common layer, at least one second common layer, and a common electrode layer sequentially stacked in a direction away from the drive backplane; first common layers of the plurality of light-emitting devices are integrated as a whole; and second common layers of the plurality of light-emitting devices are integrated as a whole,
wherein an orthogonal projection of the first common layer on the drive backplane is within an orthogonal projection of the second common layer on the drive backplane.

In some exemplary embodiments of this disclosure, each of the light-emitting devices further includes:
a first light-emitting layer disposed between the first common layer and the second common layer;
first light-emitting layers of the plurality of light-emitting devices are combined to form a first light-emitting unit layer;
wherein the orthogonal projection of the first common layer on the drive backplane is within an orthogonal projection of the first light-emitting unit layer on the drive backplane; and
the orthogonal projection of the first light-emitting unit layer on the drive backplane is within the orthogonal projection of the second common layer on the drive backplane.

In some exemplary embodiments of this disclosure, a number of the first common layers is N, and in the direction away from the drive backplane, the first common layers are sequentially numbered as 1, 2, 3 . . . i−1, i . . . N, wherein 1≤i≤N;
wherein an orthogonal projection of a first common layer numbered as i−1 on the drive backplane is within an orthogonal projection of a first common layer numbered as i on the drive backplane.

In some exemplary embodiments of this disclosure, the at least one first common layer includes:
a hole injection layer disposed on a side of the first electrode away from the drive backplane, hole injection layers of the plurality of light-emitting devices being integrated as a whole; and
a hole transport layer disposed on a side of the hole injection layer away from the drive backplane, hole transport layers of the plurality of light-emitting devices being integrated as a whole,
wherein an orthogonal projection of the hole injection layer on the drive backplane is within an orthogonal projection of the hole transport layer on the drive backplane.

In some exemplary embodiments of this disclosure, the at least one first common layer further includes:
an electron blocking layer disposed on a side of the hole transport layer away from the drive backplane, electron blocking layers of the plurality of light-emitting devices being integrated as a whole,
wherein the orthogonal projection of the hole transport layer on the drive backplane is within an orthogonal projection of the electron blocking layer on the drive backplane.

In some exemplary embodiments of this disclosure, a number of the second common layers is X, and in the direction away from the drive backplane, the second common layers are sequentially numbered as 1, 2, 3 . . . k−1, k . . . X, wherein 1≤k≤X;
wherein an orthogonal projection of a second common layer numbered as k−1 on the drive backplane is within an orthogonal projection of a second common layer numbered as k on the drive backplane.

In some exemplary embodiments of this disclosure, the at least one second common layer includes:
an electron transport layer disposed on a side of the first common layer away from the drive backplane, electron transport layers of the plurality of light-emitting devices being integrated as a whole; and
an electron injection layer disposed on a side of the electron transport layer away from the drive backplane, electron injection layers of the plurality of light-emitting devices being integrated as a whole,
wherein an orthogonal projection of the electron transport layer on the drive backplane is located within an orthogonal projection of the electron injection layer on the drive backplane.

In some exemplary embodiments of this disclosure, the at least one second common layer further includes:
a hole blocking layer disposed between the first common layer and the electron transport layer, hole blocking layers of the plurality of light-emitting devices being integrated as a whole,
wherein an orthogonal projection of the hole blocking layer on the drive backplane is within the orthogonal projection of the electron transport layer on the drive backplane.

In some exemplary embodiments of this disclosure, each of the light-emitting devices further includes:
a light-emitting auxiliary layer disposed between the first common layer and the first light-emitting layer;
light-emitting auxiliary layers of the plurality of light-emitting devices are combined to form a light-emitting auxiliary unit layer;
wherein the orthogonal projection of the first common layer on the drive backplane is within an orthogonal projection of the light-emitting auxiliary unit layer on the drive backplane; and
the orthogonal projection of the light-emitting auxiliary unit layer on the drive backplane is within the orthogonal projection of the first light-emitting unit layer on the drive backplane.

In some exemplary embodiments of this disclosure, each of the light-emitting devices further includes:
a second light-emitting layer disposed between the first light-emitting layer and the second common layer; and
at least one third common layer disposed between the first light-emitting layer and the second light-emitting layer, third common layers of the plurality of light-emitting devices being integrated as a whole,
wherein the orthogonal projection of the first common layer on the drive backplane is within an orthogonal projection of the third common layer on the drive backplane; and
the orthogonal projection of the third common layer on the drive backplane is within the orthogonal projection of the second common layer on the drive backplane.

In some exemplary embodiments of this disclosure, a number of the third common layers is L, and in the direction away from the drive backplane, the third common layers are sequentially numbered as 1, 2, 3 . . . l−1, 1 . . . L, wherein 1≤1≤L;
wherein an orthogonal projection of a third common layer numbered as l−1 on the drive backplane is within an orthogonal projection of a third common layer numbered as 1 on the drive backplane.

In some exemplary embodiments of this disclosure, the at least one third common layer includes:
a first charge generation layer disposed between the first light-emitting layer and the second light-emitting layer, first charge generation layers of the plurality of light-emitting devices being integrated as a whole; and
a second charge generation layer disposed between the first charge generation layer and the second light-emitting layer, second charge generation layers of the plurality of light-emitting devices being integrated as a whole,
wherein an orthogonal projection of the first charge generation layer on the drive backplane is within an orthogonal projection of the second charge generation layer on the drive backplane.

In some exemplary embodiments of this disclosure, common electrode layers of the plurality of light-emitting devices are integrated as a whole;
wherein an orthogonal projection of each second common layer on the drive backplane is within an orthogonal projection of the common electrode layer on the drive backplane.

In some exemplary embodiments of this disclosure, the drive backplane includes a base substrate, a drive circuit layer disposed on a side of the base substrate, and a planarization layer disposed on a side of the drive circuit layer away from the base substrate;
the common electrode layer has a central region and an edge region surrounding the central region of the common electrode layer, and at least a part of the edge region of the common electrode layer is in contact with the drive circuit layer.

In some exemplary embodiments of this disclosure, the second common layer has a central region and an edge region surrounding the central region of the second common layer, and at least a part of the edge region of the second common layer is in contact with the planarization layer.

In some exemplary embodiments of this disclosure, each of the light-emitting devices further includes:
a covering layer disposed on a side of the common electrode layer away from the drive backplane, covering layers of the plurality of light-emitting devices being integrated as a whole;
wherein the orthogonal projection of the common electrode layer on the drive backplane is within an orthogonal projection of the covering layer on the drive backplane.

In some exemplary embodiments of this disclosure, the display panel further includes an encapsulation layer disposed on a side of the covering layer away from the drive backplane; and the encapsulation layer includes:
a first inorganic layer disposed on the side of the covering layer away from the drive backplane;
an organic layer disposed on a side of the first inorganic layer away from the drive backplane, an orthogonal projection of the organic layer on the drive backplane being within an orthogonal projection of the first inorganic layer on the drive backplane; and
a second inorganic layer covering the organic layer and the first inorganic layer not covered by the organic layer,
wherein the orthogonal projection of the covering layer on the drive backplane is within the orthogonal projection of the first inorganic layer on the drive backplane.

In some exemplary embodiments of this disclosure, the display panel has a to-be-evaporated region and a non-evaporation region at a periphery of the to-be-evaporated region, and the first common layer and the second common layer are located in the to-be-evaporated region;
the display panel further includes a plurality of first isolation pillars and a plurality of second isolation pillars disposed on a side of the pixel definition layer away from the drive backplane, the first isolation pillars are located in the to-be-evaporated region, the second isolation pillars are located in the non-evaporation region, and a height of each second isolation pillar is greater than a height of each first isolation pillar.

In some exemplary embodiments of this disclosure, the to-be-evaporated region includes a display region and a non-display region at a periphery of the display region;
among the plurality of first isolation pillars, part of the first isolation pillars are located in the display region, and part of the first isolation pillars are located in the non-display region.

In some exemplary embodiments of this disclosure, among the plurality of first isolation pillars, orthogonal projections of at least part of the first isolation pillars on the drive backplane do not overlap with the orthogonal projection of the first common layer on the drive backplane;
among the plurality of first isolation pillars, orthogonal projections of at least part of the first isolation pillars on the drive backplane do not overlap with the orthogonal projection of the second common layer on the drive backplane.

In some exemplary embodiments of this disclosure, the height of each second isolation pillar is 0.1-5 μm greater than the height of each first isolation pillar.

In some exemplary embodiments of this disclosure, the display panel has a to-be-evaporated region and a non-evaporation region at a periphery of the to-be-evaporated region;
the display panel includes:
a drive backplane;
a pixel definition layer disposed on a side of the drive backplane; and
a plurality of first isolation pillars and a plurality of second isolation pillars disposed on a side of the pixel definition layer away from the drive backplane, the first isolation pillars being located in the to-be-evaporated region, the second isolation pillars being located in the non-evaporation region, and a height of each second isolation pillar being greater than a height of each first isolation pillar.

In some exemplary embodiments of this disclosure, the to-be-evaporated region includes a display region and a non-display region at a periphery of the display region;
among the plurality of first isolation pillars, part of the first isolation pillars are located in the display region, and part of the first isolation pillars are located in the non-display region.

In some exemplary embodiments of this disclosure, the height of each second isolation pillar is 0.1-5 μm greater than the height of each first isolation pillar.

According to a second aspect of this disclosure, there is provided a display apparatus, including the display panel according to the first aspect.

In the display panel provided by this disclosure, the first common layers of the plurality of light-emitting devices are integrated as a whole, and the second common layers of the plurality of light-emitting devices are integrated as a whole; the orthogonal projection of each first common layer on the drive backplane is within the orthogonal projection of each second common layer on the drive backplane, which may avoid damage to edges of the first common layer during the evaporation process, and improve the quality of the display panel.

### BRIEF DESCRIPTION OF THE DRAWINGS

The above and other features and advantages of this disclosure will become more apparent from the detailed descriptions of exemplary embodiments with reference with the accompanying drawings.

FIG. 1 is a schematic view of an evaporation assembly of a display panel in the related art.

FIG. 2 shows a sectional view along A-A′ direction in FIG. 1 and a schematic view of a combined structure of an evaporation source.

FIG. 3 is a design view of an opening of a mask for forming an OLED light-emitting device through evaporation in the related art.

FIG. 4 is a schematic plan view of a display panel according to an exemplary embodiment of this disclosure.

FIG. 5 is a sectional view of an embodiment along B-B′ direction in FIG. 4.

FIG. 6 is a design view of openings in a mask of an evaporation assembly of a display panel according to an exemplary embodiment of this disclosure.

FIG. 7 is a schematic view of a first mask according to an exemplary embodiment of this disclosure.

FIG. 8 is a schematic view of a second mask according to an exemplary embodiment of this disclosure.

FIG. 9 is a schematic view of a third mask according to an exemplary embodiment of this disclosure.

FIG. 10 is a schematic view of a fourth mask according to an exemplary embodiment of this disclosure.

FIG. 11 is a schematic view of a fifth mask according to an exemplary embodiment of this disclosure.

FIG. 12 is a schematic view of a mask when a magnetic plate and a pressing plate are lifted according to an exemplary embodiment of this disclosure.

FIG. 13 is a schematic view of a mask when a magnetic plate and a pressing plate are lowered for pressing according to an exemplary embodiment of this disclosure.

FIG. 14 is a sectional view of an embodiment along C-C′ direction in FIG. 4.

FIG. 15 is a sectional view of another embodiment along C-C′ direction in FIG. 4.

FIG. 16 is a sectional view of another embodiment along B-B′ direction in FIG. 4.

FIG. 17 is a sectional view of yet another embodiment along C-C′ direction in FIG. 4.

FIG. 18 is a design view of openings in a mask of an evaporation assembly of a display panel according to another exemplary embodiment of this disclosure.

### REFERENCE NUMERALS

100—evaporation assembly system; 110—magnetic plate; 120—pressing plate; 130—mask assembly; 140—base platform; 150—evaporation source; 160—to-be-evaporated panel; 161—isolation pillar; 10—display panel; 101—display region; 102—peripheral region; 11—base substrate; 12—drive circuit layer; 13—planarization layer; 2—pixel definition layer; 31—first electrode; 32—first common layer; 33—first light-emitting layer; 39—light-emitting auxiliary layer; 34—second common layer; 35—common electrode layer; 36—covering layer; 37—second light-emitting layer; 38—third common layer; 41—first mask; 411—first opening; 42—second mask; 421—second opening; 43—third mask; 431—third opening; 4311—dividing portion; 4312—sub-opening; 44—fourth mask; 441—fourth opening; 45—fifth mask; 451—fifth opening; 46—sixth mask; 47—seventh mask; 5—isolation pillar; 51—first isolation pillar; 52—second isolation pillar; 6—encapsulation layer.

### DETAILED DESCRIPTION

Exemplary embodiments will now be described more fully with reference to the accompanying drawings. However, the exemplary embodiments may be implemented in various forms and should not be construed as limiting the embodiments set forth herein. Rather, these embodiments are provided so that this disclosure will be thorough and complete, and will fully convey the concepts of the exemplary embodiments to those skilled in the art. The described features, structures, or characteristics may be combined in any suitable manner in one or more embodiments. In the following description, numerous specific details are provided to give a thorough understanding of the embodiments of this disclosure.

In the drawings, thicknesses of regions and layers may be exaggerated for clarity. The same reference numerals in the drawings denote the same or similar structures, and thus their detailed descriptions will be omitted.

The described features, structures, or characteristics may be combined in any suitable manner in one or more embodiments. In the following description, numerous specific details are provided to give a thorough understanding of the embodiments of this disclosure. However, those skilled in the art will recognize that the technical solutions of this disclosure may be practiced without one or more of the specific details, or with other methods, components, materials, etc. In other cases, well-known structures, materials, or operations are not shown or described in detail to avoid obscuring the main technical concepts of this disclosure.

When a structure is described as being “on” another structure, it may mean that the structure is integrally formed on the other structure, or that the structure is “directly” disposed on the other structure, or that the structure is “indirectly” disposed on the other structure through an additional structure.

The terms “a”, “an”, “the”, “said”, and “at least one” are used to indicate the presence of one or more elements/components/etc. ; the terms “including” and “having” are used to indicate an open-ended inclusion and mean that there may be additional elements/components/etc. in addition to those listed; and the terms “first”, “second” etc. are used merely as labels and are not intended to impose numerical limitations on the objects.

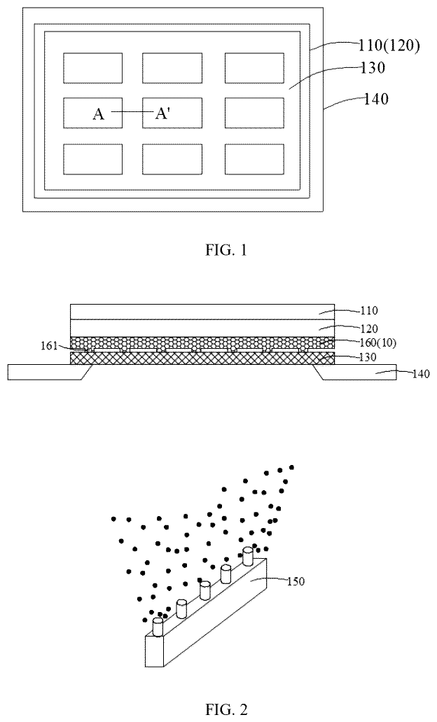

In the related art, relevant film layers in OLED light-emitting devices are typically formed through evaporation using a metal mask. As shown in FIG. 1 and FIG. 2, the evaporation assembly system 100 mainly includes a base platform 140, a mask assembly 130, a pressing plate 120, a magnetic plate 110, etc. The mask assembly 130 may include a plurality of masks. During evaporation, a to-be-evaporated panel 160 enters an evaporation chamber and aligns with the mask to ensure an evaporation process. After alignment, the pressing plate 120 and the magnetic plate 110 descend, and the mask is lifted upward by magnetic force to tightly adhere to the to-be-evaporated panel 160. Once evaporation is completed, the to-be-evaporated panel 160 moves away from the mask. Typically, the to-be-evaporated panel 160 includes a drive backplane, a pixel definition layer disposed on a side of the drive backplane, and isolation pillars 161 disposed on a side of the pixel definition layer. The isolation pillars 161 are used to support the mask during the evaporation, to prevent the mask from sticking to the to-be-evaporated panel 160.

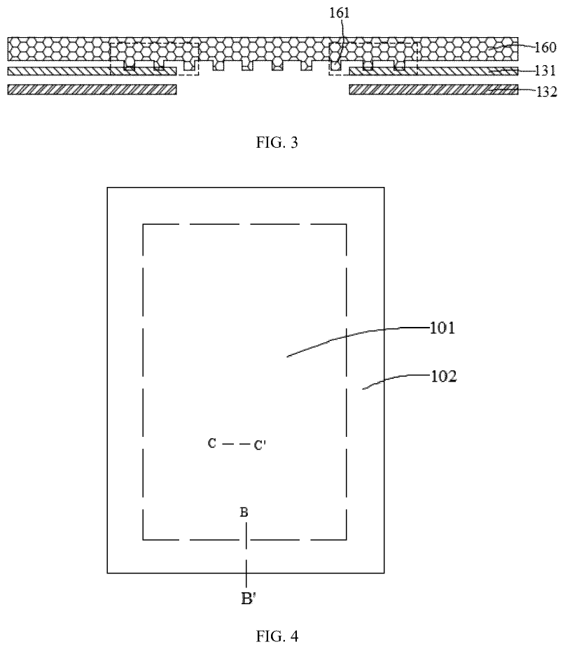

As shown in FIG. 3, when evaporating the relevant film layers of the OLED light-emitting device, the openings of the masks are approximately in the same size. For example, if the OLED light-emitting device requires the evaporation of a first evaporation layer and a second evaporation layer, a mask for the first evaporation layer formed by the evaporation is a first mask 131, and a mask for the second evaporation layer formed by the evaporation is a second mask 132. The openings of the first mask 131 and the second mask 132 are roughly equal in size. In this case, after the first evaporation layer is completed, the to-be-evaporated panel enters the evaporation chamber and aligns with the second mask 132 for the evaporation. During this process, the first evaporation layer on the isolation pillar in contact with the second mask 132 is easily scratched by the second mask 132, causing the evaporation material at this location to peel off. The peeled-off evaporation material may directly result in dark spot defects on the to-be-evaporated panel 160 at that location and also affect subsequent encapsulation, thereby leading to poor reliability.

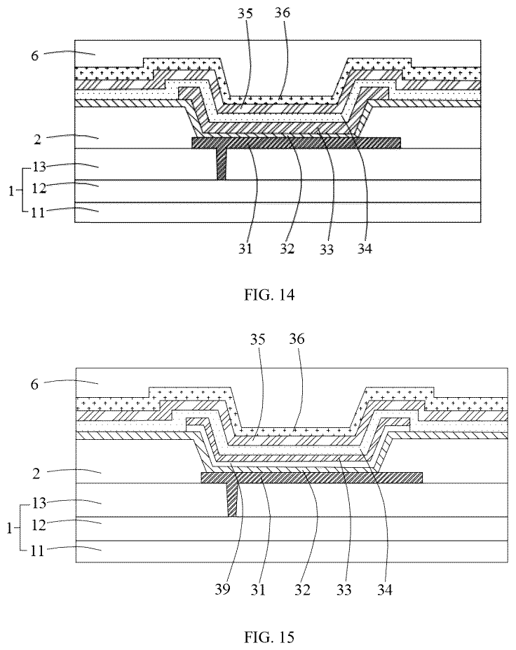

As shown in FIG. 4, FIG. 5, and FIG. 14, this disclosure provides a display panel 10, which includes a drive backplane 1, a pixel definition layer 2 disposed on a side of the drive backplane 1, and a plurality of light-emitting devices separated by the pixel definition layer 2. Each light-emitting device includes a first electrode 31, at least one first common layer 32, and at least one second common layer 34 sequentially stacked in a direction away from the drive backplane 1. The first common layers 32 of the plurality of light-emitting devices are integrated as a whole, and the second common layers 34 of the plurality of light-emitting devices are integrated as a whole. An orthogonal projection of the first common layer 32 on the drive backplane 1 is within an orthogonal projection of the second common layer 34 on the drive backplane 1.

In the display panel 10 provided by this disclosure, the first common layers 32 of the plurality of light-emitting devices are integrated as a whole, and the second common layers 34 of the plurality of light-emitting devices are integrated as a whole; the orthogonal projection of each first common layer 32 on the drive backplane 1 is within the orthogonal projection of each second common layer 34 on the drive backplane 1, which may avoid damage to edges of the first common layer 32 during the evaporation process, and improve the quality of the display panel 10.

Hereinafter, components of the display panel 10 provided by the embodiments of this disclosure will be described in detail with reference to the accompanying drawings.

As shown in FIG. 5, this disclosure provides a display panel 10, which includes a drive backplane 1, a pixel definition layer 2 disposed on a side of the drive backplane 1, and a plurality of light-emitting devices separated by the pixel definition layer 2. Specifically, the pixel definition layer 2 may include a plurality of openings, and each opening defining a range of a light-emitting device.

The drive backplane 1 includes a base substrate 11 and a drive circuit layer 12 disposed on a side of the base substrate 11. The drive circuit layer 12 includes drive circuits to drive the light-emitting devices to emit light. The drive circuits may include pixel circuits and peripheral circuits. The pixel circuits may be 7T1C, 7T2C, 6TIC, or 6T2C pixel circuits, as long as they can drive the light-emitting devices to emit light. The number of pixel circuits is the same as the number of light-emitting devices. The pixel circuits are connected to the light-emitting devices in one-to-one correspondence to individually control the light emission of the light-emitting devices. Herein, nTmC represents that one pixel circuit includes n transistors (represented by “T”) and m capacitors (represented by “C”). The peripheral circuits are connected to the pixel circuits, for inputting driving signals to the pixel circuits to control the light emission of the light-emitting devices. The peripheral circuits may include gate drive circuits and light emission control circuits, and may also include other circuits. The specific structure of the peripheral circuit is not limited here. The drive backplane 1 further includes a planarization layer 13 disposed on a side of the drive circuit layer 12 away from the base substrate 11.

As shown in FIG. 5 and FIG. 14, the light-emitting devices include a first electrode 31, at least one first common layer 32, and at least one second common layer 34 sequentially stacked in a direction away from the drive backplane 1. The first common layers 32 of the plurality of light-emitting devices are integrated as a whole, and the second common layers 34 of the plurality of light-emitting devices are integrated as a whole. That is, both the first common layer 32 and the second common layer 34 are continuous material layers. An orthogonal projection of the first common layer 32 on the drive backplane 1 is within an orthogonal projection of the second common layer 34 on the drive backplane 1. In other words, the second common layer 34 may encapsulate the first common layer 32 within it.

The first electrode 31 may serve as an anode of each light-emitting device. The first electrode 31 is disposed between the drive backplane 1 and the pixel definition layer 2, and there is a plurality of first electrodes 31. The plurality of openings in the pixel definition layer 2 expose the first electrodes in one-to-one correspondence. An orthogonal projection of the opening in the pixel definition layer 2 on the drive backplane 1 is within an orthogonal projection of the first electrode on the drive backplane 1.

A number of first common layers 32 may be one or more. In some embodiments of this disclosure, the number of first common layers 32 is N, and in the direction away from the drive backplane 1, the first common layers 32 are sequentially numbered as 1, 2, 3 . . . i−1, i . . . N, wherein 1≤i<N. An orthogonal projection of the first common layer 32 numbered as i−1 on the drive backplane 1 is within an orthogonal projection of the first common layer 32 numbered as i on the drive backplane 1.

In some embodiments of this disclosure, the at least one first common layer 32 includes a hole injection layer and a hole transport layer, and may further include an electron blocking layer. The hole injection layer is disposed on a side of the first electrode 31 away from the drive backplane 1, and the hole injection layers of the plurality of light-emitting devices are integrated as a whole. The hole transport layer is disposed on a side of the hole injection layer away from the drive backplane 1, and the hole transport layers of the plurality of light-emitting devices are integrated as a whole. The electron blocking layer is disposed on a side of the hole transport layer away from the drive backplane 1, and the electron blocking layers of the plurality of light-emitting devices are integrated as a whole. An orthogonal projection of the hole injection layer on the drive backplane 1 is within an orthogonal projection of the hole transport layer on the drive backplane 1. An orthogonal projection of the hole transport layer on the drive backplane 1 is within an orthogonal projection of the electron blocking layer on the drive backplane 1. Furthermore, a thickness of the hole injection layer may be 5~30 nm; a thickness of the hole transport layer may be 100~2000 nm; and a thickness of the electron blocking layer may be 5~100 nm. It should be noted that each first common layer 32 (the hole injection layer, the hole transport layer, the electron blocking layer) has a central region and an edge region surrounding the central region. The edge region of each first common layer 32 has a thickness that gradually decreases in a direction away from its central region.

In this embodiment, the number of the first common layers 32 is three. In the direction away from the drive backplane 1, the three first common layers 32 are sequentially numbered as 1, 2, and 3. Among them, the first common layer 32 numbered as 1 may be the hole injection layer, the first common layer 32 numbered as 2 may be the hole transport layer, and the first common layer 32 numbered as 3 may be the electron blocking layer.

The number of the second common layers 34 may be one or more. In some embodiments of this disclosure, the number of the second common layers 34 is X, and in the direction away from the drive backplane 1, the second common layers 34 are sequentially numbered as 1, 2, 3 . . . k−1, k . . . X, wherein 1≤k≤X. An orthogonal projection of the second common layer 34 numbered as k−1 on the drive backplane 1 is within an orthogonal projection of the second common layer 34 numbered as k on the drive backplane 1.

In some embodiments of this disclosure, the at least one second common layer 34 includes an electron transport layer and an electron injection layer, and may further include a hole blocking layer. The electron transport layer is disposed on a side of the first common layer away from the drive backplane 1, and the electron transport layers of the plurality of light-emitting devices are integrated as a whole. The electron injection layer is disposed on a side of the electron transport layer away from the drive backplane 1, and the electron injection layers of the plurality of light-emitting devices are integrated as a whole. The hole blocking layer is disposed between the first common layer and the electron transport layer, and the hole blocking layers of the plurality of light-emitting devices are integrated as a whole. An orthogonal projection of the hole blocking layer on the drive backplane 1 is within an orthogonal projection of the electron transport layer on the drive backplane 1, and the orthogonal projection of the electron transport layer on the drive backplane 1 is within an orthogonal projection of the electron injection layer on the drive backplane 1. Furthermore, the thickness of the hole blocking layer may be 5~100 nm; the thickness of the electron transport layer may be 20~100 nm; and the thickness of the electron injection layer may be 1~10 nm. It should be noted that each second common layer 34 (the hole blocking layer, the electron transport layer, and the electron injection layer) has a central region and an edge region surrounding the central region. The edge region of each second common layer 34 has thickness that gradually decreases in the direction away from its central region.

In this embodiment, the number of the second common layers 34 is three. In the direction away from the drive backplane 1, the three second common layers 34 are sequentially numbered as 1, 2, and 3. Among them, the second common layer 34 numbered as 1 may be the hole blocking layer, the second common layer 34 numbered as 2 may be the electron transport layer, and the second common layer 34 numbered as 3 may be the electron injection layer.

As shown in FIG. 5 and FIG. 14, the common electrode layers 35 of the plurality of light-emitting devices are integrated as a whole. The common electrode layer 35 may serve as a cathode layer of the light-emitting devices. The orthogonal projections of the second common layers 34 on the drive backplane 1 are within the orthogonal projection of the common electrode layer 35 on the drive backplane 1. For example, the orthogonal projections of the hole blocking layer, the electron transport layer, and the electron injection layer on the drive backplane 1 are all within the orthogonal projection of the common electrode layer 35 on the drive backplane 1. The common electrode layer 35 also has a central region and an edge region away from the central region of the common electrode layer 35. A thickness of the edge region of the common electrode layer 35 gradually decreases in a direction away from the central region. Furthermore, at least a part of the edge region of the common electrode layer 35 is in contact with the drive circuit layer 12.

In the display panel 10 of this disclosure, edge regions of other film layers may also be in contact with different film layers. For example, in some embodiments, the at least one first common layer 32 includes a hole injection layer, a hole transport layer, and an electron blocking layer. Each of the hole injection layer, the hole transport layer, and the electron blocking layer also has a central region and an edge region surrounding the central region. The edge region of the hole injection layer is in contact with the pixel definition layer 2, the edge region of the hole transport layer may be in contact with the pixel definition layer 2 or the planarization layer 13, and similarly, the edge region of the electron blocking layer may be in contact with the pixel definition layer 2 or the planarization layer 13.

Furthermore, the second common layer 34 has a central region and an edge region surrounding the central region of the second common layer 34. At least a part of the edge region of the second common layer 34 is in contact with the planarization layer 13.

The light-emitting device further includes a first light-emitting layer 33 disposed between the first common layer 32 and the second common layer 34. In a direction perpendicular to the drive backplane 1, the first light-emitting layer 33 corresponds one-to-one with the openings in the pixel definition layer 2. The first light-emitting layers 33 of the plurality of light-emitting devices are combined to form a first light-emitting unit layer. The orthogonal projection of the first common layer 32 on the drive backplane 1 is within the orthogonal projection of the first light-emitting unit layer on the drive backplane 1, and the orthogonal projection of the first light-emitting unit layer on the drive backplane 1 is within an orthogonal projection of the second common layer 34 on the drive backplane 1. That is, an outer edge of the first common layer 32 is within an outer edge of the first light-emitting unit layer formed by the combination of the first light-emitting layers 33 of the plurality of light-emitting devices. The outer edge of the first light-emitting unit layer formed by the combination of the first light-emitting layers 33 of the plurality of light-emitting devices is within the outer edge of the second common layer 34. The thickness of the first light-emitting layer 33 may be 20~100 nm.

The light-emitting device further includes a covering layer 36 disposed on a side of the common electrode layer 35 away from the drive backplane 1. The covering layers 36 of the plurality of light-emitting devices are integrated as a whole. The orthogonal projection of the common electrode layer 35 on the drive backplane 1 is within an orthogonal projection of the covering layer 36 on the drive backplane 1. The covering layer 36 includes a first covering layer and a second covering layer in the direction away from the drive backplane 1. A refractive index of the first covering layer is greater than that of the second covering layer, and a thickness of the second covering layer is less than that of the first covering layer. A material of the second covering layer may be inorganic or organic, with a refractive index of 1.3-1.8@460 nm.

In some embodiments of this disclosure, as shown in FIG. 5, a distance between the outer edge of the first common layer 32 and the outer edge of the first light-emitting unit layer formed by the combination of the first light-emitting layers 33 of the plurality of light-emitting devices is d1. A distance between the outer edge of the first light-emitting unit layer and the outer edge of the second common layer 34 is d2. A distance between the outer edge of the second common layer 34 and the outer edge of the common electrode layer 35 is d3. A distance between the outer edge of the common electrode layer 35 and the outer edge of the covering layer 36 is d4. Here, d1, d2, and d4 are all smaller than d3. This can ensure the connection between the common electrode layer 35 and the drive circuit layer 12. In this disclosure, the outer edge refers to an outermost edge of each film layer away from the central region.

As shown in FIG. 15, in some embodiments of this disclosure, the light-emitting device further includes a light-emitting auxiliary layer 39 disposed between the first common layer 32 and the first light-emitting layer 33. In the direction perpendicular to the drive backplane 1, the light-emitting auxiliary layer 39 corresponds one-to-one with the openings in the pixel definition layer 2. The light-emitting auxiliary layers 39 of the plurality of light-emitting devices are combined to form a light-emitting auxiliary unit layer. The orthogonal projection of the first common layer 32 on the drive backplane 1 is within an orthogonal projection of the light-emitting auxiliary unit layer on the drive backplane 1. The orthogonal projection of the light-emitting auxiliary unit layer on the drive backplane 1 is within the orthogonal projection of the first light-emitting unit layer on the drive backplane 1. That is, the outer edge of the light-emitting auxiliary unit layer is within the outer edge of the first light-emitting unit layer.

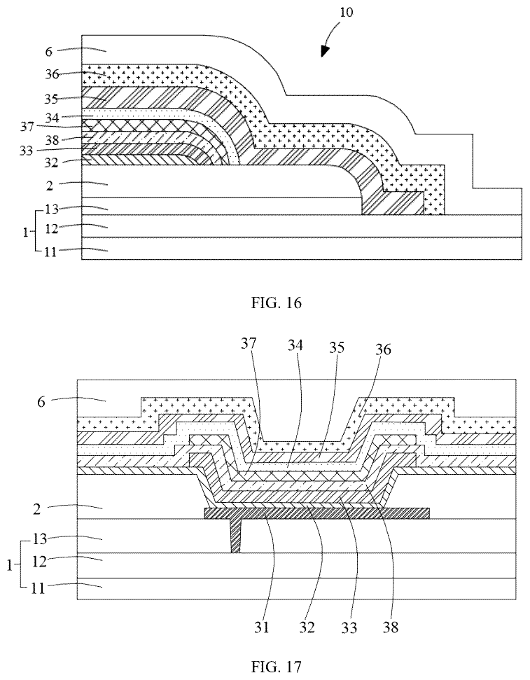

As shown in FIG. 16 and FIG. 17, in some embodiments of this disclosure, the light-emitting device further includes a second light-emitting layer 37 and at least one third common layer 38. The second light-emitting layer 37 is disposed between the first light-emitting layer 33 and the second common layer 34. In the direction perpendicular to the drive backplane 1, the second light-emitting layer 37 corresponds one-to-one with the openings in the pixel definition layer 2. The at least one third common layer 38 is disposed between the first light-emitting layer 33 and the second light-emitting layer 37, and the third common layers 38 of the plurality of light-emitting devices are integrated as a whole.

The orthogonal projection of the first common layer 32 on the drive backplane 1 is within an orthogonal projection of the third common layer 38 on the drive backplane 1. The orthogonal projection of the third common layer 38 on the drive backplane 1 is within the orthogonal projection of the second common layer 34 on the drive backplane 1.

The number of the third common layers 38 may be one or more. In some embodiments of this disclosure, the number of the third common layers 38 is Y, and in the direction away from the drive backplane 1, the third common layers 38 are sequentially numbered as 1, 2, 3 . . . l−1, 1 . . . L, wherein 1≤1<L. An orthogonal projection of the third common layer 38 numbered as l−1 on the drive backplane 1 is within an orthogonal projection of the third common layer 38 numbered as 1 on the drive backplane 1.

In some embodiments of this disclosure, the at least one third common layer 38 includes a first charge generation layer and a second charge generation layer, respectively for generating electrons or holes. The first charge generation layer is disposed between the first light-emitting layer 33 and the second light-emitting layer 37, and the first charge generation layers of the plurality of light-emitting devices are integrated as a whole. The second charge generation layer is disposed between the first charge generation layer and the second light-emitting layer 37, and the second charge generation layers of the plurality of light-emitting devices are integrated as a whole. An orthogonal projection of the first charge generation layer on the drive backplane 1 is within the orthogonal projection of the second charge generation layer on the drive backplane 1.

The display panel 10 further includes an encapsulation layer 6 disposed on a surface of a side of the covering layer 36 away from the drive backplane 1. It may be used to protect the light-emitting devices and block external water and oxygen from corroding the light-emitting devices.

In some embodiments of this disclosure, thin-film encapsulation (TFE) may be used to achieve encapsulation. Specifically, an encapsulation layer 6 may include a first inorganic layer, an organic layer, and a second inorganic layer. The first inorganic layer is disposed on a surface of the covering layer 36 away from the drive backplane 1. The organic layer is disposed on a surface of the first inorganic layer away from the drive backplane 1, and a boundary of the organic layer is defined inside a boundary of the first inorganic layer, i.e., an orthogonal projection of the organic layer on the drive backplane 1 is within an orthogonal projection of the first inorganic layer on the drive backplane 1. The second inorganic layer covers the organic layer and the first inorganic layer not covered by the organic layer. The second inorganic layer may block the intrusion of water and oxygen while the flexible organic layer achieves planarization. The orthogonal projection of the covering layer 36 on the drive backplane 1 is within an orthogonal projection of the first inorganic layer on the drive backplane 1.

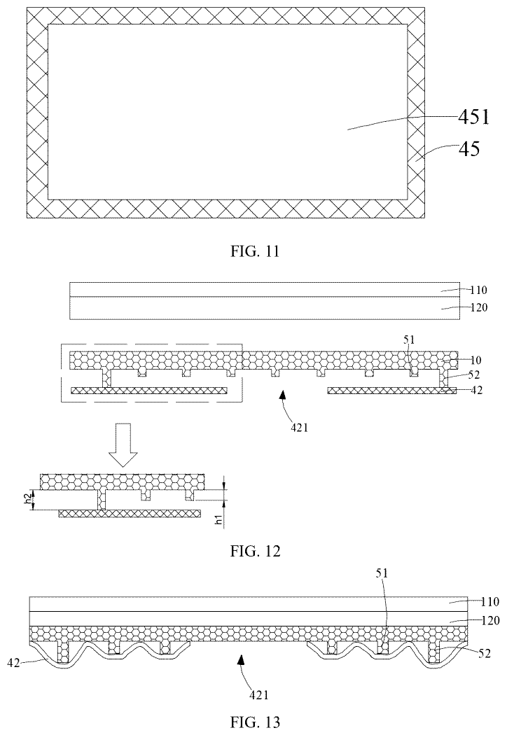

As shown in FIG. 12 and FIG. 13, in some embodiments of this disclosure, the display panel 10 has a to-be-evaporated region 103 and a non-evaporation region 104 located at a periphery of the to-be-evaporated region 103. The first common layer 32 and the second common layer 34 are both located in the to-be-evaporated region 103. The display panel 10 further includes isolation pillars, such as a plurality of first isolation pillars 51 and a plurality of second isolation pillars 525, disposed on a side of the pixel definition layer 2 away from the drive backplane 1. The first isolation pillars 51 are located in the to-be-evaporated region 103, and the second isolation pillars 52 are located in the non-evaporation region 104. A height of the second isolation pillars 52 is greater than that of the first isolation pillars 51. Heights of the first isolation pillars 51 and the second isolation pillars 52 may be set according to actual conditions. In some exemplary embodiments of this disclosure, the height of the first isolation pillars 51 is 1-3 μm, and the height of the second isolation pillars 52 is 0.1-5 μm higher than that of the first isolation pillars 51, but this disclosure is not limited thereto.

The to-be-evaporated region 103 includes a display region 101 and a non-display region 102 located at a periphery of the display region 101. Among the plurality of first isolation pillars 51, part of the first isolation pillars 51 are located in the display region 101, and part of the first isolation pillars 51 are located in the non-display region 102. The plurality of first isolation pillars 51 may be arranged at intervals on a side of the pixel definition layer 2 away from the drive backplane 1, and the specific arrangement and quantity will not be limited. Among the plurality of first isolation pillars 51, orthogonal projections of the part of first isolation pillars 51 on the drive backplane 1 overlap with the orthogonal projections of the first common layer 32 or the second common layer 34 on the drive backplane 1, while orthogonal projections of the part of the first isolation pillars 51 on the drive backplane 1 do not overlap with the orthogonal projections of the first common layer 32 or the second common layer 34 on the drive backplane 1. Specifically, the orthogonal projections of the part of the first isolation pillars 51 on the drive backplane 1 are at a periphery of the orthogonal projections of the first common layer 32 or the second common layer 34 on the drive backplane 1. The orthogonal projections of the second isolation pillars 52 on the drive backplane 1 do not overlap with the orthogonal projections of the evaporated film layers formed in the to-be-evaporated region 103, such as the first common layer 32, the second common layer 34, the first light-emitting layer 33, the third common layer 38, the common electrode layer 35, the covering layer 36, the encapsulation layer 37, etc., on the drive backplane 1.

The display panel 10 provided by this disclosure may be manufactured by using the display panel evaporation assembly shown in FIG. 4 to FIG. 6. The display panel evaporation assembly includes at least one first mask 41 and at least one second mask 42. The first mask 41 is provided with a first opening 411 for forming the first common layer 32, and the second mask 42 is provided with a second opening 421 for forming the second common layer 34. The size of the first opening 411 is smaller than that of the second opening 421.

The evaporation assembly of the display panel includes at least one first mask 41 and at least one second mask 42. The first mask 41 is provided with a first opening 411, and the size of the first opening 411 is smaller than that of the second opening 421. This can prevent the second mask 42 from scratching off the already evaporated first common layer 32, thereby improving the quality of the display panel 10.

The evaporation assembly of the display panel provided by this disclosure may be applied to the evaporation process for forming an OLED display panel 10. As shown in FIG. 12, the display panel 10 has a to-be-evaporated region 103 and a non-evaporation region 104 located at a periphery of the to-be-evaporated region 103. The to-be-evaporated region 103 includes a display region 101 and a non-display region 102. The plurality of light-emitting devices are located in the display region 101, and correspondingly, the first common layer 32 and the second common layer 34 are also located in the to-be-evaporated region 103.

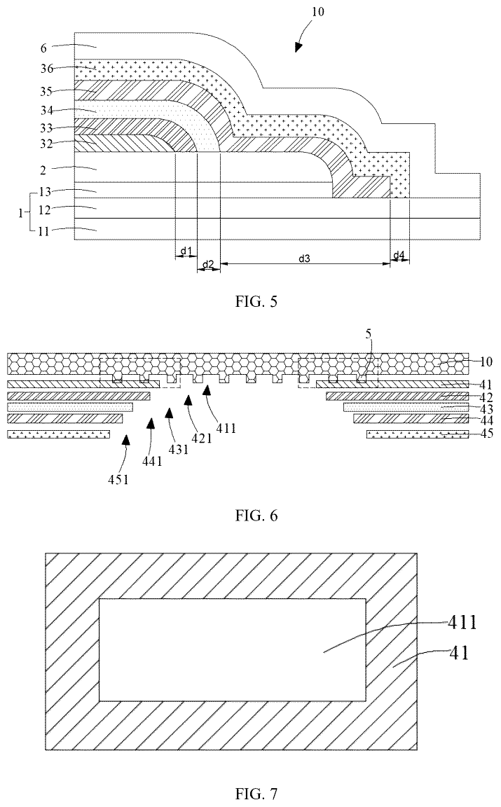

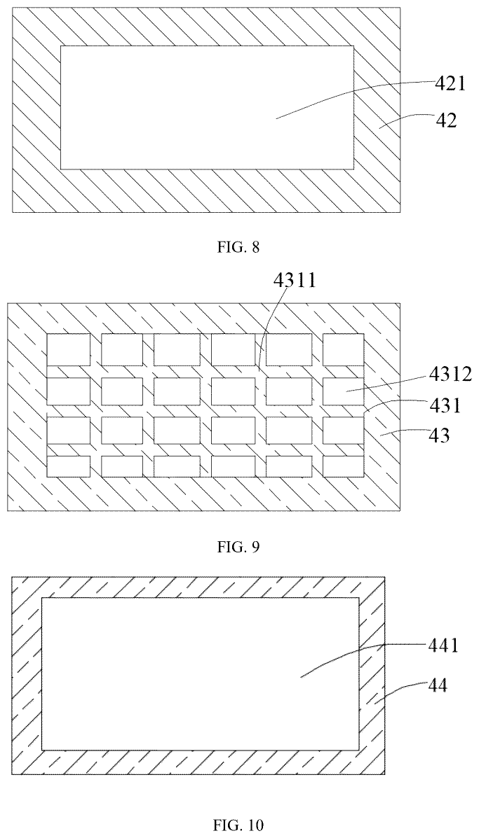

As shown in FIG. 5, FIG. 6, FIG. 7, and FIG. 8, the evaporation assembly of the display panel includes at least one first mask 41 and at least one second mask 42. The first mask 41 is used for evaporating to form the first common layer 32, and the second mask 42 is used for evaporating to form the second common layer 34. The number of the first masks 41 is equal to the number of the first common layers 32, and the number of the second masks 42 is equal to the number of the second common layers 34.

The first mask 41 is provided with a first opening 411. The size of the first opening 411 may be designed according to the size of the corresponding first common layer 32 to be formed. The second mask 42 is provided with a second opening 421, and the size of the first opening 411 is smaller than that of the second opening 421. In this disclosure, the size of the first opening 411 of each of the first masks 41 is smaller than that of the second opening 421 of each of the second masks 42. In this disclosure, the size of the first opening 411 being smaller than that of the second opening 421 refers to when the evaporation alignment is completed, an orthogonal projection of the first opening 411 on the drive backplane 1 is within an orthogonal projection of the second opening 421 on the drive backplane 1.

Referring to FIG. 1, FIG. 5, and FIG. 6, the evaporation assembly of the display panel further includes a base platform 140, a pressing plate 120, and a magnetic plate 110. During the evaporation, the display panel 10 to be evaporated enters the evaporation chamber. At this time, the display panel 10 to be evaporated includes the drive backplane 1 and the pixel definition layer 2, but does not include the first common layer 32 and the second common layer 34. When it is necessary to evaporate to form the first common layer 32, the display panel 10 to be evaporated is placed into the evaporation chamber and aligned with the first mask 41. After the alignment, the pressing plate 120 and the magnetic plate 110 descend, and the first mask 41 is lifted upward by magnetic force to tightly adhere to the display panel 10. At this time, the evaporation source 150 begins to evaporate to form the first common layer 32 that has a pattern and a size basically the same as that of the first opening 411. After the first common layer 32 is evaporated, the display panel 10 to be evaporated enters the evaporation chamber of the second common layer 34 and aligns with the second mask 42 for evaporation. After the alignment, the evaporation source 150 begins to evaporate to form the second common layer 34 with a pattern the same as the size of the second opening 421. Since the size of the first opening 411 is smaller than that of the second opening 421, an orthogonal projection of the first common layer 32 formed by the evaporation on the drive backplane 1 is within an orthogonal projection of the second opening 421 of the second mask 42 on the drive backplane 1. At this time, the second mask 42 is not in contact the first common layer 32 formed by the evaporation, so that the first common layer 32 will not be scratched off.

In this disclosure, the number of first common layers 32 may be one or more, and correspondingly, the number of first masks 41 may also be one or more. When there is a plurality of first masks 41, the sizes of the first openings 411 of each first mask 41 may be different. For example, in some embodiments, the number of first common layers 32 is N, and in the direction away from the drive backplane 1, the first common layers 32 are sequentially numbered as 1, 2, 3 . . . i−1, i . . . N, wherein 1≤i<N. A number of the first masks 41 is M, and the first masks 41 are sequentially numbered as 1, 2, 3 . . . j−1, j . . . M, wherein 1≤j≤M and M=N. The first mask 41 numbered as j is used to form the first common layer 32 numbered as i, wherein i=j. A size of the first opening 411 of the first mask 41 numbered as j−1 is smaller than that of the first mask 41 numbered as j.

For example, the number of first common layers 32 is three, and in the direction away from the drive backplane 1, the three first common layers 32 are sequentially numbered as 1, 2, and 3. The first common layer 32 numbered as 1 may be the hole injection layer, the first common layer 32 numbered as 2 may be the hole transport layer, and the first common layer 32 numbered as 3 may be the electron blocking layer. Correspondingly, the number of the first masks 41 is three, and the three first masks 41 are sequentially numbered as 1, 2, and 3. The first mask 41 numbered as 1 is used to form the hole injection layer, the first mask 41 numbered as 2 is used to form the hole transport layer, and the first mask 41 numbered as 3 is used to form the electron blocking layer. A size of the first opening 411 of the first mask 41 numbered as 1 is smaller than a size of the first opening 411 of the first mask 41 numbered as 2, and a size of the first opening 411 of the first mask 41 numbered as 2 is smaller than a size of the first opening 411 of the first mask 41 numbered as 3.

In this disclosure, the number of the second common layers 34 may be one or more, and correspondingly, the number of second masks 42 may also be one or more. When there is a plurality of second masks 42, the sizes of the second openings 421 of each second mask 42 may be different. For example, in some embodiments, the number of the second common layers 34 is X, and in the direction away from the drive backplane 1, the second common layers 34 are sequentially numbered as 1, 2, 3 . . . k−1, k . . . X, wherein 1≤k≤X. The number of the second masks 42 is Y, and the second masks 42 are sequentially numbered as 1, 2, 3 . . . g−1, g . . . Y, wherein 1≤g≤Y and Y=X. The second mask 42 numbered as g is used to form the second common layer 34 numbered as k, wherein g=k. A size of the second opening 421 of the second mask 42 numbered as g−1 is smaller than size of the second opening 421 of the second mask 42 numbered as g.

For example, the number of the second common layers 34 is three, and in the direction away from the drive backplane 1, the three second common layers 34 are sequentially numbered as 1, 2, and 3. The second common layer 34 numbered as 1 may be the hole blocking layer, the second common layer 34 numbered as 2 may be the electron transport layer, and the second common layer 34 numbered as 3 may be the electron injection layer. Correspondingly, the number of the second masks 42 is three, and the three second masks 42 are sequentially numbered as 1, 2, and 3. The second mask 42 numbered as 1 is used to form the hole blocking layer, the second mask 42 numbered as 2 is used to form the electron transport layer, and the second mask 42 numbered as 3 is used to form the electron injection layer. A size of the second opening 421 of the second mask 42 numbered as 1 is smaller than a size of the second opening 421 of the second mask 42 numbered as 2, and a size of the second opening 421 of the second mask 42 numbered as 2 is smaller than size of the second opening 421 of the second mask 42 numbered as 3.

As shown in FIG. 5, FIG. 6, and FIG. 9, the evaporation assembly of the display panel further includes a third mask 43. The third mask 43 is provided with a third opening 431. The third opening 431 includes a dividing portion 4311 and a plurality of sub-openings 4312 divided by the dividing portion 4311. The plurality of sub-openings 4312 are used to form the first light-emitting layers 33 of the light-emitting devices in one-to-one correspondence. The size of the first opening 411 of each first mask 41 is smaller than that of the third opening 431, and the size of the second opening 421 of each second mask 42 is larger than that of the third opening 431. That is, after the evaporation and alignment is completed, an orthogonal projection of the first opening 411 of any first mask 41 on the drive backplane 1 is within an orthogonal projection of the third opening 431 on the drive backplane 1, and the orthogonal projection of the third opening 431 on the drive backplane 1 is within the orthogonal projection of the second opening 421 of any second mask 42 on the drive backplane 1.

As shown in FIG. 5, FIG. 6, and FIG. 10, in some embodiments of this disclosure, the display panel evaporation assembly further includes a fourth mask 44. The fourth mask 44 is provided with a fourth opening 441, which is used to form the common electrode layer 35. The size of the second opening 421 of each second mask 42 is smaller than that of the fourth opening 441. That is, after the evaporation alignment is completed, the orthogonal projection of the second opening 421 of any second mask 42 on the drive backplane 1 is located within the orthogonal projection of the fourth opening 441 on the drive backplane 1.

As shown in FIG. 5, FIG. 6, and FIG. 11, in some embodiments of this disclosure, the evaporation assembly of the display panel further includes a fifth mask 45. The fifth mask 45 is provided with a fifth opening 451 that is used to form a covering layer 36. The size of the fourth opening 441 is smaller than that of the fifth opening 451. That is, after the evaporation and alignment is completed, an orthogonal projection of the fourth opening 441 on the drive backplane 1 is within an orthogonal projection of the fifth opening 451 on the drive backplane 1.

Furthermore, an area difference between the first opening 411 and the third opening 431 is A1, an area difference between the third opening 431 and the second opening 421 is A2, an area difference between the second opening 421 and the fourth opening 441 is A3, and an area difference between the fourth opening 441 and the fifth opening 451 is A4. Here, A1, A2, and A4 are all smaller than A3. The area differences between the openings may be determined based on the distances between the outer edges of the evaporated film layers of the display panel 10. The opening difference between the second opening 421 and the fourth opening 441 being large can facilitate for the connection between the common electrode layer 35 and the drive circuit.

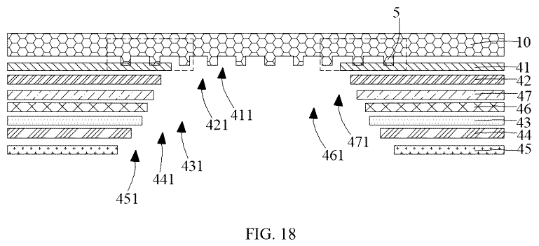

As shown in FIG. 18, in some embodiments of this disclosure, the evaporation assembly of the display panel further includes a sixth mask 46 and at least one seventh mask 47. The structure of the sixth mask 46 may refer to the third mask 43. The sixth mask 46 is provided with a sixth opening 461. The sixth opening 461 includes a dividing portion and a plurality of sub-openings divided by the dividing portion. The plurality of sub-openings are used to form the second light-emitting layers 37 of the light-emitting devices in one-to-one correspondence. The size of the third opening 431 of the third mask 43 may be smaller than that of the sixth opening 461.

The seventh mask 47 is provided with a seventh opening 471 and may be used to form the third common layer 38. A number of seventh masks 47 may be in plural, specifically equal to the number of third common layers 38. When there is a plurality of seventh masks 47, the sizes of the seventh openings 471 of each seventh mask 47 may be different. For example, in some embodiments, the number of the third common layers 38 is L, and in the direction away from the drive backplane 1, the third common layers 38 are sequentially numbered as 1, 2, 3 . . . l−1, 1 . . . L, wherein 1≤1<L. The seventh masks 47 are sequentially numbered as 1, 2, 3 . . . h−1, h . . . H, wherein 1≤h≤H and H=L. The seventh mask 47 numbered as h is used to form the third common layer 38 numbered as 1, wherein h=1. A size of the seventh opening 471 of the seventh mask 47 numbered as h−1 is smaller than a size of the seventh opening 471 of the seventh mask 47 numbered as h.

For example, the number of third common layers 38 is two, and in the direction away from the drive backplane 1, the two third common layers 38 are sequentially numbered as 1 and 2. The third common layer 38 numbered as 1 may be a first charge generation layer, and the third common layer 38 numbered as 2 may be a second charge generation layer. Correspondingly, the number of seventh masks 47 is two, and the two seventh masks 47 are sequentially numbered as 1 and 2. The seventh mask 47 numbered as 1 is used to form the first charge generation layer, and the seventh mask 47 numbered as 2 is used to form the second charge generation layer. A size of the seventh opening 471 of the seventh mask 47 numbered as 1 is smaller than a size of the seventh opening 471 of the seventh mask 47 numbered as 2.

Furthermore, the evaporation assembly of the display panel may also include a ninth mask for forming a light-emitting auxiliary layer 39. The structure of the ninth mask may refer to the third mask 43. The ninth mask is provided with a ninth opening. The ninth opening includes a dividing portion and a plurality of sub-openings divided by the dividing portion. The plurality of sub-openings are used to form the light-emitting auxiliary layers 39 of the light-emitting devices in one-to-one correspondence. A size of the ninth opening of the ninth mask may be smaller than that of the third opening 431. A size of the first opening 411 of the first mask 41 may be smaller than a size of the ninth opening of the ninth mask.

As shown in FIG. 12 and FIG. 13, in the display panel provided by this disclosure, a height h2 of the second isolation pillar 52 is greater than a height h1 of the first isolation pillar 51. In practical applications, during the processes of relative motion between the display panel 10 and the mask, such as the alignment of the mask with the display panel 10 to be evaporated or the display panel 10 to be evaporated leaving the chamber, the magnetic plate 110 and the pressing plate 120 may first lift to cancel the magnetic force. Since the second isolation pillar 52 of this disclosure is higher than the first isolation pillar 51, after the magnetic force is canceled, the first isolation pillar 51 may be detached from the mask under counterforce of the second isolation pillar 52. This not only can prevent sticking but also ensure that during the motion of the display panel 10 to be evaporated, only the second isolation pillar 52 may come into contact with the mask, while the first isolation pillars 51 at other positions may not contact with the mask due to the presence of the second isolation pillar 52. This can prevent the evaporated material on the first isolation pillars 51 from being scraped off due to the relative motion between the display panel 10 and the mask. Since the second isolation pillar 52 is located in the non-evaporation region 104, there will be no issues such as scraping the evaporated material due to the presence of the second isolation pillar 52. FIG. 12 only schematically shows a state of the second mask 42 after the magnetic force is canceled, and other masks may refer to this figure, and the detailed description will be omitted.

When the alignment is completed and the evaporation begins, the magnetic plate 110 and the pressing plate 120 descend, and the mask is lifted upward by the magnetic force to tightly adhere to the display panel 10. All isolation pillars 5, including the first isolation pillars 51 and the second isolation pillars 52, may still support the mask. As shown in FIG. 13, it illustrates the adhesion between the second mask 42 and the display panel 10 during the evaporation. This can ensure that there is no scraping between the evaporated film layers in the to-be-evaporated region and the mask, prevent the evaporated material from peeling off and ensure display quality and encapsulation quality of the display panel 10.

For example, the first common layer 32 formed by the evaporation is the first mask 41, and the second common layer 34 formed by the evaporation is the second mask 42. The first mask 41 is provided with a first opening 411, and the second mask 42 is provided with a second opening 421. During the evaporation, the display panel 10 to be evaporated enters the evaporation chamber. At this time, the display panel 10 to be evaporated includes the drive backplane 1 and the pixel definition layer 2, but does not include the first common layer 32 and the second common layer 34. When it is necessary to evaporate to form the first common layer 32, the display panel 10 to be evaporated is placed into the evaporation chamber of the first common layer 32 and aligned with the first mask 41. After the alignment, the pressing plate 120 and the magnetic plate 110 descend, and the first mask 41 is lifted upward by the magnetic force to tightly adhere to the display panel 10. At this time, the evaporation source 150 begins to evaporate to form the first common layer 32 that has a pattern and a size basically the same as that of the first opening 411. After the first common layer 32 is evaporated, the display panel 10 to be evaporated enters the evaporation chamber of the second common layer 34 and aligns with the second mask 42 for evaporation. After the alignment, the evaporation source 150 begins to evaporate to form the second common layer 34 that has a pattern and a size the same as that of the second opening 421. Since the height of the second isolation pillar 52 is greater than that of the first isolation pillar 51, during the alignment, the second isolation pillar 52 in the non-evaporation region 104 comes into contact with the second mask 42, while the first isolation pillars 51 in the to-be-evaporated region do not contact with the second mask 42. Thus, regardless of the size between the first opening 411 and the second opening 421, the first common layer 32 evaporated on the first isolation pillars 51 may not be scraped by the second mask 42. Additionally, the higher second isolation pillar 52 can facilitate avoiding the sticking between the display panel 10 and the mask.

As shown in FIG. 5, FIG. 12, and FIG. 13, this disclosure also provides a display panel 10 that includes a to-be-evaporated region 103 and a non-evaporation region 104 at a periphery of the to-be-evaporated region 103. The display panel 10 includes a drive backplane 1, a pixel definition layer 2, first isolation pillars 51, and second isolation pillars 52. The pixel definition layer 2 is disposed on a side of the drive backplane 1. The first isolation pillars 51 and the second isolation pillars 52 are disposed on a side of the pixel definition layer 2 away from the drive backplane 1. The first isolation pillars 51 are located in the to-be-evaporated region 103, and the second isolation pillars 52 are located in the non-evaporation region 104. The height of the second isolation pillars 52 is greater than that of the first isolation pillars 51. The heights of the first isolation pillars 51 and the second isolation pillars 52 may be set according to actual conditions. In some exemplary embodiments of this disclosure, a height of the first isolation pillars 51 is 1-3 μm, and a height of the second isolation pillars 52 is 0.1-5 μm higher than that of the first isolation pillars 51, but this disclosure is not limited thereto.

The to-be-evaporated region 103 includes a display region 101 and a non-display region 102 at a periphery of the display region 101. Among the plurality of first isolation pillars 51, part of the first isolation pillars 51 are located in the display region 101, and part of the first isolation pillars 51 are located in the non-display region 102. The plurality of first isolation pillars 51 may be arranged at intervals on a side of the pixel definition layer 2 away from the drive backplane 1, and the specific arrangement and quantity will not be limited.

In the display panel 10 provided by this disclosure, the height h2 of the second isolation pillar 52 is greater than the height h1 of the first isolation pillar 51. In practical applications, during the processes of relative motion between the display panel 10 and the mask, such as the alignment of the mask with the display panel 10 to be evaporated or the display panel 10 to be evaporated leaving the chamber, the magnetic plate 110 and the pressing plate 120 may be first lift to cancel the magnetic force. Since the second isolation pillar 52 of this disclosure is higher than the first isolation pillar 51, after the magnetic force is canceled, the first isolation pillar 51 may be detached from the mask under counterforce of the second isolation pillar 52. This can not only prevent sticking but also ensure that during the motion of the display panel 10 to be evaporated, only the second isolation pillar 52 may come into contact with the mask, while the first isolation pillars 51 at other positions may not contact with the mask due to the presence of the second isolation pillar 52. This can prevent the evaporated material on the first isolation pillars 51 from being scraped off due to the relative motion between the display panel 10 and the mask. Since the second isolation pillar 52 is located in the non-evaporation region 104, there will be no issues such as scraping the evaporated material due to the presence of the second isolation pillar 52.

As shown in FIG. 4, FIG. 5, and FIG. 14, this disclosure also provides a manufacturing method for a display panel, including following steps:
step S100: providing a drive backplane 1;
step S200: forming a plurality of first electrodes 31 on a side of the drive backplane 1;
step S300: forming a pixel definition layer 2 on a side of the first electrodes 31 away from the drive backplane 1; the pixel definition layer 2 being provided with a plurality of openings, and the openings exposing the first electrodes 31 in one-to-one correspondence;
step S400: forming at least one first common layer 32 on a side of the first electrodes 31 and the pixel definition layer 2 away from the drive backplane 1, and each first common layer 32 being a continuous film layer;
step S500: forming at least one second common layer 34 on a side of the first common layer 32 away from the drive backplane 1, and each second common layer 34 being a continuous film layer.

An orthogonal projection of the first common layer 32 on the drive backplane 1 is within an orthogonal projection of the second common layer 34 on the drive backplane 1.

The openings in the pixel definition layer 2 define a range of one of the light-emitting devices, and each light-emitting device includes a first electrode 31, a first common layer 32, and a second common layer 34. The first common layers 32 of the plurality of light-emitting devices are integrated as a whole, and the second common layers 34 of the plurality of light-emitting devices are integrated as a whole.

In step S400, forming at least one first common layer 32 on the side of the first electrodes 31 and the pixel definition layer 2 away from the drive backplane 1 may be achieved using the first mask 41 in the evaporation assembly of the display panel described above. In step S500, forming at least one second common layer 34 on the side of the first common layer 32 away from the drive backplane 1, and each second common layer 34 being a continuous film layer, may be achieved by using the second mask 42 in the evaporation assembly of the display panel described above. The specific method may refer to the above content and will not be detailed here.

This disclosure also provides a display apparatus, including the display panel 10. The display panel 10 may be the display panel 10 in any above implementations, and its specific structure and beneficial effects may refer to the embodiments of the display panel 10 described above, which will not be repeated here. The display apparatus of this disclosure may be electronic devices such as mobile phones, tablets, televisions, etc., which will not be listed exhaustively.

It should be noted that, although the various steps of the method of this disclosure are described in a particular order in the figures, it is not required or implied that the steps must be performed in the particular order, or all the illustrated steps must be performed to achieve the desired result. Additionally or alternatively, some steps may be omitted, or multiple steps may be combined into one step to be performed, and/or one step is decomposed into multiple steps to be performed.

It should be understood that application of this disclosure is not limited to the detailed structure and arrangement of components provided in the present specification. This disclosure can have other embodiments, and can be implemented and carried out in various ways. The foregoing variations and modifications fall within the scope of this disclosure. It should be understood that the contents disclosed and defined in this specification may extend to all alternative combinations of two or more of the individual features that are mentioned or apparent from the text and/or drawings. All of these different combinations form various alternative aspects of this disclosure. The embodiments described herein explain the best modes known for carrying out this disclosure, and will allow those skilled in the art to utilize this disclosure.

1. A display panel, comprising a drive backplane, a pixel definition layer disposed on a side of the drive backplane, and a plurality of light-emitting devices separated by the pixel definition layer, wherein each of the light-emitting devices comprises a first electrode, at least one first common layer, at least one second common layer, and a common electrode layer sequentially stacked in a direction away from the drive backplane; first common layers of the plurality of light-emitting devices are integrated as a whole; and second common layers of the plurality of light-emitting devices are integrated as a whole;
wherein an orthogonal projection of the first common layer on the drive backplane is within an orthogonal projection of the second common layer on the drive backplane.

2. The display panel according to claim 1, wherein each of the light-emitting devices further comprises a first light-emitting layer disposed between the first common layer and the second common layer;
first light-emitting layers of the plurality of light-emitting devices are combined to form a first light-emitting unit layer;
wherein the orthogonal projection of the first common layer on the drive backplane is within an orthogonal projection of the first light-emitting unit layer on the drive backplane; and the orthogonal projection of the first light-emitting unit layer on the drive backplane is within the orthogonal projection of the second common layer on the drive backplane.

3. The display panel according to claim 1, wherein a number of the first common layers is N, and in the direction away from the drive backplane, the first common layers are sequentially numbered as 1, 2, 3 . . . i−1, i . . . N, wherein 1≤i≤N;
wherein an orthogonal projection of a first common layer numbered as i−1 on the drive backplane is within an orthogonal projection of a first common layer numbered as i on the drive backplane.

4. The display panel according to claim 1, wherein the at least one first common layer comprises:
a hole injection layer disposed on a side of the first electrode away from the drive backplane, hole injection layers of the plurality of light-emitting devices being integrated as a whole; and
a hole transport layer disposed on a side of the hole injection layer away from the drive backplane, hole transport layers of the plurality of light-emitting devices being integrated as a whole,
wherein an orthogonal projection of the hole injection layer on the drive backplane is within an orthogonal projection of the hole transport layer on the drive backplane.

5. The display panel according to claim 4, wherein the at least one first common layer further comprises:
an electron blocking layer disposed on a side of the hole transport layer away from the drive backplane, electron blocking layers of the plurality of light-emitting devices being integrated as a whole,
wherein the orthogonal projection of the hole transport layer on the drive backplane is within an orthogonal projection of the electron blocking layer on the drive backplane.

6. The display panel according to claim 1, wherein a number of the second common layers is X, and in the direction away from the drive backplane, the second common layers are sequentially numbered as 1, 2, 3 . . . k−1, k . . . X, wherein 1<k≤X;
wherein an orthogonal projection of a second common layer numbered as k−1 on the drive backplane is within an orthogonal projection of a second common layer numbered as k on the drive backplane.

7. The display panel according to claim 1, wherein the at least one second common layer comprises:
an electron transport layer disposed on a side of the first common layer away from the drive backplane, electron transport layers of the plurality of light-emitting devices being integrated as a whole; and
an electron injection layer disposed on a side of the electron transport layer away from the drive backplane, electron injection layers of the plurality of light-emitting devices being integrated as a whole,
wherein an orthogonal projection of the electron transport layer on the drive backplane is located within an orthogonal projection of the electron injection layer on the drive backplane.

8. The display panel according to claim 7, wherein the at least one second common layer further comprises:
a hole blocking layer disposed between the first common layer and the electron transport layer, hole blocking layers of the plurality of light-emitting devices being integrated as a whole,
wherein an orthogonal projection of the hole blocking layer on the drive backplane is within the orthogonal projection of the electron transport layer on the drive backplane.

9. The display panel according to claim 2, wherein each of the light-emitting devices further comprises a light-emitting auxiliary layer disposed between the first common layer and the first light-emitting layer;
light-emitting auxiliary layers of the plurality of light-emitting devices are combined to form a light-emitting auxiliary unit layer;
wherein the orthogonal projection of the first common layer on the drive backplane is within an orthogonal projection of the light-emitting auxiliary unit layer on the drive backplane; and
the orthogonal projection of the light-emitting auxiliary unit layer on the drive backplane is within the orthogonal projection of the first light-emitting unit layer on the drive backplane.

10. The display panel according to claim 2, wherein each of the light-emitting devices further comprises:
a second light-emitting layer disposed between the first light-emitting layer and the second common layer; and
at least one third common layer disposed between the first light-emitting layer and the second light-emitting layer, third common layers of the plurality of light-emitting devices being integrated as a whole,
wherein the orthogonal projection of the first common layer on the drive backplane is within an orthogonal projection of the third common layer on the drive backplane; and
the orthogonal projection of the third common layer on the drive backplane is within the orthogonal projection of the second common layer on the drive backplane.

11. The display panel according to claim 10, wherein a number of the third common layers is L, and in the direction away from the drive backplane, the third common layers are sequentially numbered as 1, 2, 3 . . . l−1, 1 . . . L, wherein 1≤1≤L;
wherein an orthogonal projection of a third common layer numbered as l−1 on the drive backplane is within an orthogonal projection of a third common layer numbered as 1 on the drive backplane.

12. The display panel according to claim 10, wherein the at least one third common layer comprises:
a first charge generation layer disposed between the first light-emitting layer and the second light-emitting layer, first charge generation layers of the plurality of light-emitting devices being integrated as a whole; and
a second charge generation layer disposed between the first charge generation layer and the second light-emitting layer, second charge generation layers of the plurality of light-emitting devices being integrated as a whole,
wherein an orthogonal projection of the first charge generation layer on the drive backplane is within an orthogonal projection of the second charge generation layer on the drive backplane.

13. The display panel according to claim 1, wherein common electrode layers of the plurality of light-emitting devices are integrated as a whole;
wherein an orthogonal projection of each second common layer on the drive backplane is within an orthogonal projection of the common electrode layer on the drive backplane.

14. The display panel according to claim 13, wherein the drive backplane comprises a base substrate, a drive circuit layer disposed on a side of the base substrate, and a planarization layer disposed on a side of the drive circuit layer away from the base substrate;
the common electrode layer has a central region and an edge region surrounding the central region of the common electrode layer, and at least a part of the edge region of the common electrode layer is in contact with the drive circuit layer.

15. The display panel according to claim 14, wherein the second common layer has a central region and an edge region surrounding the central region of the second common layer, and at least a part of the edge region of the second common layer is in contact with the planarization layer.

16. The display panel according to claim 13, wherein each of the light-emitting devices further comprises:
a covering layer disposed on a side of the common electrode layer away from the drive backplane, covering layers of the plurality of light-emitting devices being integrated as a whole;
wherein the orthogonal projection of the common electrode layer on the drive backplane is within an orthogonal projection of the covering layer on the drive backplane.

17. The display panel according to claim 16, wherein the display panel further comprises an encapsulation layer disposed on a side of the covering layer away from the drive backplane; and the encapsulation layer comprises:
a first inorganic layer disposed on the side of the covering layer away from the drive backplane;
an organic layer disposed on a side of the first inorganic layer away from the drive backplane, an orthogonal projection of the organic layer on the drive backplane being within an orthogonal projection of the first inorganic layer on the drive backplane; and
a second inorganic layer covering the organic layer and the first inorganic layer not covered by the organic layer,
wherein the orthogonal projection of the covering layer on the drive backplane is within the orthogonal projection of the first inorganic layer on the drive backplane.

18. The display panel according to claim 1, wherein the display panel has a to-be-evaporated region and a non-evaporation region at a periphery of the to-be-evaporated region, and the first common layer and the second common layer are located in the to-be-evaporated region;
the display panel further comprises a plurality of first isolation pillars and a plurality of second isolation pillars disposed on a side of the pixel definition layer away from the drive backplane, the first isolation pillars are located in the to-be-evaporated region, the second isolation pillars are located in the non-evaporation region, and a height of each second isolation pillar is greater than a height of each first isolation pillar.

19.-21. (canceled)

22. A display panel, having a to-be-evaporated region and a non-evaporation region at a periphery of the to-be-evaporated region,
wherein the display panel comprises:
a drive backplane;
a pixel definition layer disposed on a side of the drive backplane; and
a plurality of first isolation pillars and a plurality of second isolation pillars disposed on a side of the pixel definition layer away from the drive backplane, the first isolation pillars being located in the to-be-evaporated region, the second isolation pillars being located in the non-evaporation region, and a height of each second isolation pillar being greater than a height of each first isolation pillar.

23.-24. (canceled)

25. A display apparatus, comprising a display panel, wherein the display panel comprises a drive backplane, a pixel definition layer disposed on a side of the drive backplane, and a plurality of light-emitting devices separated by the pixel definition layer.
wherein each of the light-emitting devices comprises a first electrode, at least one first common layer, at least one second common layer, and a common electrode layer sequentially stacked in a direction away from the drive backplane: first common layers of the plurality of light-emitting devices are integrated as a whole; and second common layers of the plurality of light-emitting devices are integrated as a whole;
wherein an orthogonal projection of the first common layer on the drive backplane is within an orthogonal projection of the second common layer on the drive backplane.
